(19) United States
(12) Patent Application Publication
(10) Pub. No.: US 2026/0063730 A1
(43) Pub. Date: Mar. 5, 2026

(54) METHOD FOR MONITORING THE STATUS OF A PLURALITY OF BATTERY CELLS IN AN ENERGY STORAGE SYSTEM

(71) Applicant: Hitachi Energy Ltd, Zürich (CH)

(72) Inventors: Haofeng BAI, Västerås (SE); Mats LARSSON, Rupperswil (CH); Anton SODERBLOM, Enköping (SE); Philippe NOISETTE, Plan-les-Ouates (CH); Hongyang ZHANG, Stockholm (SE); Jan SVENSSON, Västerås (SE); Lexuan MENG, Västerås (SE)

(21) Appl. No.: 19/106,130

(22) PCT Filed: Sep. 1, 2022
(86) PCT No.: PCT/EP2022/074363

§ 371 Date: Feb. 24, 2025

(51) Int. Cl. G01R 31/396; G01R 31/374; G01R 31/3842; G01R 31/389; G01R 31/392; H01M 10/42; H01M 10/48

(52) U.S. Cl. CPC G01R 31/396; G01R 31/374; G01R 31/3842; G01R 31/389; G01R 31/392; H01M 10/425; H01M 10/486; H01M 2010/4271; H01M 2010/4278

(57) ABSTRACT

A method for monitoring a status of an energy storage system connected to a power converter is disclosed. The energy storage system comprises a plurality of interconnected energy storage cells, and the power converter is configured to output power from the energy storage system to a power transmission system and to charge the energy storage system with power from the power transmission system. The method comprises generating, by the power converter, an electrical signal injected into the energy storage system, measuring a response signal generated in response to the injected electrical signal, and determining a status of the energy storage system based on the received response signal.

### FIELD OF THE INVENTION

The present invention relates to the field of electric power transmission systems, and in particular to energy storages for use in such power systems.

### BACKGROUND OF THE INVENTION

Electric power transmission systems need to provide electric power in a reliable fashion. Therefore, such technologies often comprise energy storage systems for balancing and smoothing demand and power swings on the electrical grid. Preferably, the energy storage systems may store energy during off-peak periods and discharge energy to the electrical grid during on-peak periods, for example to provide fast frequency response and inertia response.

An example of such energy storage systems comprises a plurality of interconnected energy storage cells, such as series-and/or parallel-connected battery cells or supercapacitors. The energy storage system may be connected to a power converter which may operate in a bidirectional manner for outputting the discharge energy to the power transmission system and charging the energy storage cells from the same.

It is of great importance to monitor the status of the energy storage system to ensure a reliable performance. This may be performed by checking the condition of the energy storage cells during charging and/or discharging of the energy storage system, and may indicate, for instance, state-of-health (SoH) of the energy storage cells.

However, considering the ever-growing need for uninterruptible power supply as well as transmission and distribution system support, it would be beneficial to provide improved techniques for monitoring the status of such systems.

### SUMMARY

This object, among others, is achieved by a method and control unit as claimed in the appended independent claims. Preferred embodiments are specified in the dependent claims.

Hence, according to a first aspect a method for monitoring a status of an energy storage system connected to a power converter is provided, wherein the energy storage system comprises a plurality of interconnected energy storage cells and the power converter is configured to output power from the energy storage system to a power transmission system and to charge the energy storage system with power from the power transmission system. The method comprises generating, by the power converter, an electrical signal injected into the energy storage system, measuring a response signal generated in response to the injected electrical signal, and determining a status of the energy storage system based on the received response signal.

According to a second aspect, a control unit configured to monitor a status of an energy storage system according to the first aspect is provided. The control unit comprises an electrical signal generating function configured to cause the power converter to inject an electrical signal into the energy storage system, and a status determining function configured to measure a response signal, generated in response to the injected electrical signal, and determine a status of the energy storage system based on the response.

The inventive concept outlined above is based on the realisation that the power converter can be used to inject an electrical signal into the energy storage system to determine a status of the energy storage system. This is particularly beneficial over prior art systems relying on the load current or the charging current for checking the condition of the energy storage, as the present invention allows for the status of the energy storage system to be monitored also when the energy storage system is in standby mode, i.e., not being charged or discharged. Using the power converter for generating the electrical signal may prove advantageous when the energy storage system is used for grid frequency support, as the time-window during which the energy storage system is connected to load may be very small, such as in the order of 1 second. Determining the status of the energy storage system based on a load current that is available for such short time window may prove difficult, as the number of datapoints risks to be too limited. A battery management system (BMS) updating at a frequency of 10 Hz may for example result in only 10 data points during a time window of 1 second, which may lead to a relatively low accuracy in the status monitoring. By instead using a dedicated electrical signal generated by the power converter, the status of the energy storage system may be monitored also at times when the energy storage system is not being charged or discharged. This, in turn, allows for faults to be detected at an early stage irrespectively of the presence of a load current.

The electrical signal may also be referred to as a circulating current passing between the power converter and the energy storage system. This may be understood as the electrical signal having a very small or negligible impact on the power transmission system, or, in different words, is not “seen” by the external system to which the power converter and energy storage system are connected.

The response signal may thus be a signal generated by the energy storage system in response to the electrical signal injected into the system, thereby forming part of a circulating current. However, it will be appreciated that the response signal may also be a signal generated by a sensor or other device, such as e.g. a BMS, measuring the system's response to the injected electrical signal.

Beneficially, the generation of the electric signal, and thus the determination of the status of the energy storage system, may be performed regularly, such as every hour or every day. In further options it may be performed randomly upon request, such as after each operation of the energy storage system, or in connection with a manual check. Further, the duration of the signal may be selected based on the need for data length.

In the context of the present disclosure, the term “energy storage system” may generally refer to energy storage solutions for storing electrical energy and supplying it to designated loads as a primary or supplementary source, and for voltage and frequency regulation. Preferably, the energy storage system may be dimensioned for medium voltage to high voltage DC.

By the term “energy storage cell” may generally be understood a device capable of accepting electric energy, storing electric energy, and releasing electric energy. Thus, the energy storage cell may refer to a device that is capable of repeatedly being (re)charged. Examples of such devices include supercapacitors and secondary battery cells. The energy storage cells may be interconnected, preferably in series, in a stack configuration, to form an energy module. A group of interconnected energy storage modules may be referred to as an energy storage string, and a plurality of strings may be grouped into an energy storage bank.

It will be appreciated that the status of the energy storage system may be determined on different levels, such as for individual energy storage cells, individual energy storage modules, on string level, or for a complete energy storage bank.

The status of the energy storage system may refer to a charging condition, such as the state of health (SoH), or a connection status of the system (such as cables, busbars, switches, and the like).

By “power transmission system” is generally meant a structure for transmission and/or distribution of electric power, such as AC or DC. The power transmission system may in some examples be referred to as an electric power transmission network, a transmission network, a power grid, or a grid.

The term “power converter” generally refers to a device for converting electric energy between AC and DC, or DC to DC. The power converter, which may also be referred to as an inverter, may be configured to change AC power to DC to charge the energy storage system, and DC power that is discharged from the energy storage system into active or reactive power that can be supplied to the (AC) power transmission system. Thus, the power converter may be referred to as a bidirectional converter. The power converter may for instance be a modular multilevel converter (MMC).

The control unit, or controller, may be understood as a device or circuitry that is capable of outputting instructions for controlling the operation of the power converter to inject the electric signal into the energy storage system, receiving information pertaining to the response signal, and processing the received information to determine a status of the energy storage system. The control unit may be structurally integrated in the energy storage system or arranged physically remote from the system. In some examples, parts of the functionality, or the entire functionality, of the control unit may be performed in a cloud-based service. This may for instance apply to the analysis of the received signal or additional input from sensors or a battery monitoring system.

The electrical signal may preferably be tuned to reduce the energy exchange between the power converter and the energy storage system. This may for instance be achieved by using an electrical signal for which the average power is zero or at least negligible. The electrical signal may thus be an AC, for instance having a current form conforming to a sinusoidal shape, a square wave, a sawtooth, a triangular shape, or the like.

The electrical signal may comprise a frequency component being below the Nyquist frequency, that is, having a highest frequency being less than one-half of a sampling frequency of a control system of the power converter.

Further, in some embodiments the electrical signal may comprise a frequency being an integer multiple of a fundamental frequency of the power transmission system to reduce the electrical signal's impact on the active power seen by the power transmission system. Second and third order harmonics of the fundamental frequency of the power transmission system can be found in the power converter control system for balancing and modulation purposes, so it may be advantageous to utilise these frequencies.

The amplitude of the electrical signal may be selected to be low enough to have a limited or negligible effect on the system equipment, but high enough to be measurable. Studies have shown that an amplitude of 10% or less of an amplitude of a charging current or load current of the energy storage system may be sufficiently small to not disturb the system equipment.

According some embodiments, determining the status of the energy storage system may comprise calculating an impedance based on a voltage and a current of the received response signal and comparing the calculated impedance with a reference value associated with the energy storage system. The reference value may for instance be an expected value of an energy storage cell or equipment such as switches and busbars of the system and may be obtained from previously performed measurements on the energy storage system, or from a supplier of the energy storage system.

A real or imaginary part of the impedance may be used to determine a state of health (SoH) of the energy storage system. The selection of the real or imaginary part may depend on which of the parameters having the highest linearity with the SoH and being less frequency dependent. Often, the real part may be more accurate as the real part has been observed to double at the end of life and change very little with frequency.

According to some embodiments, the response signal may comprise information indicating a temperature of the energy storage system. The temperature may be used to determine the status of the energy storage system by comparing the temperature with a reference value, such as an expected or ideal temperature. The reference value may, for instance, be based on previous measurements, a predetermined temperature limit, or a pre-defined thermal model. An increased temperature may for instance indicate a bad electrical connection with high contact resistance.

As already mentioned, the processing may be performed by a control unit located at the energy storage system or remotely, such as for instance in a cloud-based service.

The invention may be embodied as computer-readable instructions for controlling a programmable computer in such manner that it performs the method outlined above. Such instructions may be distributed in the form of a computer-program product comprising a computer-readable medium storing the instructions. In particular, the instructions may be loaded in a control unit responsible for controlling a control unit as described above in connection with the second aspect. It is noted that embodiments of the invention relate to all possible combinations of features recited in the claims. Further, it will be appreciated that the various embodiments described for the method according to the first aspect are all combinable with embodiments of the control unit as defined in accordance with the second aspect.

### BRIEF DESCRIPTION OF DRAWINGS

These and other aspects will now be described in more detail with reference to the appended drawings showing embodiments.

FIG. 1 illustrates an energy storage system and a power converter connecting the energy storage system to a power transmission system according to an embodiment of the invention.

FIG. 2 illustrates an energy storage system and a modular multilevel converter according to an embodiment.

FIG. 3 is a flowchart outlining a method for monitoring a status of an energy storage system according to an embodiment.

All the figures are schematic, not necessarily to scale and generally only show parts which are necessary to elucidate the embodiments, wherein other parts may be omitted or merely suggested. Like reference numerals refer to like elements throughout the description.

### DETAILED DESCRIPTION

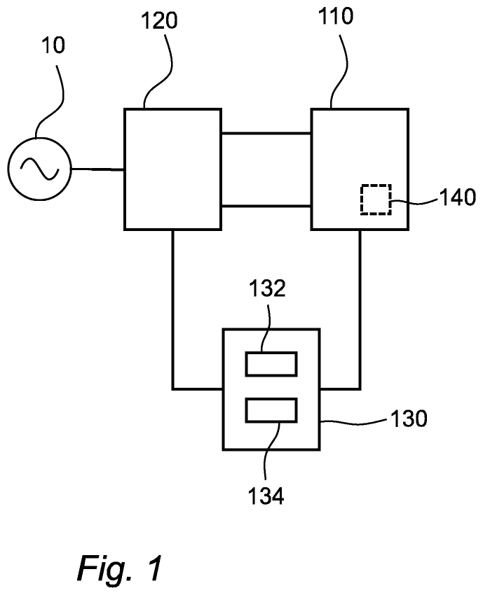

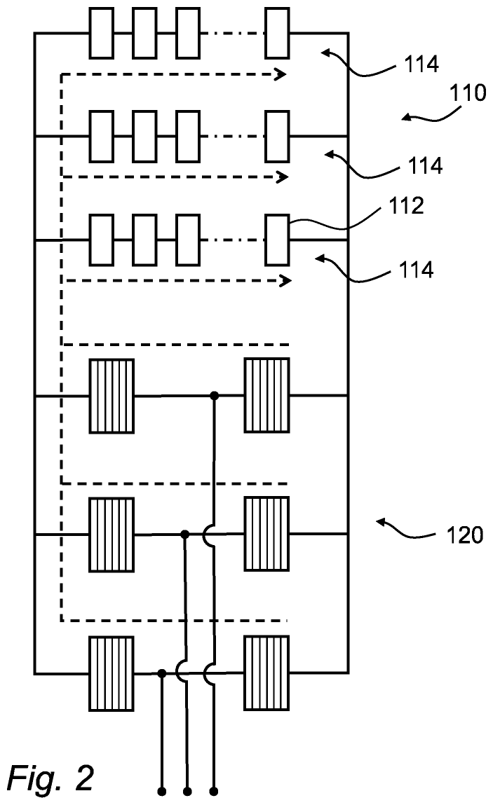

The present aspects will now be described more fully hereinafter with reference to the accompanying drawings, in which currently preferred embodiments are shown. FIG. 1 schematically illustrates an energy storage system 110 operatively connected to a power converter 120 and a control unit 130. The energy storage system 110 comprises a plurality of interconnected energy storage cells, as will be discussed in more detail in connection with FIG. 2, configured to output power from the energy storage system 110 and to a power transmission system 10 via the power converter 120. The energy storage system 110 is further configured to be charged with electric energy supplied from the power transmission system 10 via the power converter 120, which hence may be considered as a bidirectional power converter 120. With this configuration, the energy storage system 110 may function as an uninterruptible power supply as well as provide transmission and distribution system support.

The power converter 120 may for example be a modular multilevel converter (MMC), a converter type which is known to be associated with relatively low harmonics generation and relatively low energy losses. The power converter 120 may be configured to generate an electrical signal that is injected into the energy storage system 110 for monitoring purposes. The electrical signal may be understood as a circulating current passing between the power converter 120 and the energy storage system 110, and the response signal returning from the energy storage system 110 may be analysed for determining a status of the energy storage system. The power converter 120 may for example impose a voltage with controlled frequency and amplitude in the converter arms either regularly, such as every hour or every day, or randomly upon request, such as after each operation or in connection with a manual check. The resulting current at the same frequency may then be recorded and analysed to determine a status of the energy storage system 110 or components thereof. The analysis may for example include a comparison of the voltage and current of the received signal, preferably at the frequency selected for the signal injected into the energy storage system 110. This may give an indication of the impedance, which may be compared with an expected value or a reference value to provide an indication of the status of the energy storage system 110.

The frequency of the imposed voltage may preferably be lower than 50% of the system sampling frequency. The power converter control system commonly samples at kHz rates, whereas BMS for batteries and supercapacitors commonly samples at a frequency range of several Hz to several kHz. Further, the frequency of the injected signal may in some examples be selected as an integer of the fundamental frequency of the power transmission system 10, such as the grid, as this may have a negligible impact on the active power seen by the power transmission system 10. Further, as second and third order harmonics may be found in the power converter control system for balancing and for modulation purposes, it might be beneficial to utilize these frequencies.

The voltage amplitude of the injected signal may be selected such that the resulting current does not result in an over current in the energy storage system 110, and further such that amplitude of the injected current does not generate too high losses but still is possible to measure with ample accuracy.

Given the above considerations, it will be appreciated that the selected frequency and amplitude of the generated electrical signal may vary from case to case depending on the actual configuration of the power converter 120, the energy storage system 110 and the power transmission system 10 the energy storage system 110 is supporting.

As illustrated in the present figure, the energy storage system 110 may further comprise a battery management system (BMS) 140 configured to monitor and control the state of the energy storage cells of the energy storage system 110. Advantageously, the BMS 140 may be configured to generate data indicating, for instance, the voltage, current or temperature at the energy storage system 110 in general, or individual energy storage cells in particular.

Hence, there are several different options when it comes to measuring a response signal generated in response to the injected electrical signal: by means of the BMS or the power converter controller, or by means of separate sensors dedicated to the measuring of, for instance, the above-mentioned parameters.

The controller, or control unit 130, may be communicatively connected to the energy storage system 110 as well as the power converter 120. The control unit 130 may comprise an electrical signal generating function 132 configured to cause the power converter 120 to inject the electrical signal into the energy storage system 110, and a status determining function 134 configured to measure the response signal received at the power converter 120 or provided by a sensor such as e.g. the BMS 140. Depending on how the response signal is recorded, and how it is analysed, data could be retrieved from different levels of the energy storage system 110. The data could, for instance, be collected at storage cell level, indicating a status of individual storage cells, or at module or string level. Further, the status of the entire energy storage system 110, or energy storage bank, may be determined. The response signal may for example be analysed to determine the state of health (SoH) of the energy storage system 110, or components thereof. The SoH may be determined or estimated based on the impedance of the resulting signal.

The real part of the impedance may be dominated by the internal resistance, or equivalent series resistance (ESR), and therefore be used as an indication of the SoH, whereas the imaginal part of the impedance may reflect the effective capacitance or inductance of the energy storage cells. Further, the current injected by the electric signal may introduce changes in temperature of the energy storage cells. The temperature response may be compared with a pre-determined thermal model to determine a status of the energy storage cells.

The response signal may further be analysed to determine a connection status of the energy storage system 110. Poor electrical contact and open points due to e.g. installation fault or human mis-operation may lead to an increased impedance. High contact resistance may also be detected as an increase in temperature, caused by the current of the injected signal.

The control unit 130 may be structurally integrated in the energy storage system 110 or the power converter 120 or provided as a physically separate entity. In alternative configurations, the control unit 130 may be a remote unit, for example implemented as a cloud-based functionality. Further, it will be appreciated that one or several of the tasks performed by the control unit 130 may be distributed, either functionally or structurally, such as the electric signal generating function 132 being for instance arranged at, or integrated with, the power converter 120 whereas the status determining function 134 is arranged at a remote location, such as in the cloud.

FIG. 2 illustrates an embodiment in which the power converter 120 is a three-phase MMC, comprising three converter arms, wherein each arm is connected to a respective phase of the power transmission system 10. The MMC 120 is further connected to an energy storage system 110, which may be similarly configured as the one described above in connection with FIG. 1. The energy storage system 110 illustrated in FIG. 2 comprises a plurality of energy storage cells 112, in the present example connected into modules grouped into three strings 114 connected in parallel to the MMC 120. Each of the energy storage cells 112 may comprise a secondary cell or a capacitor device configured to repeatedly be charged and discharged via the MMC 120.

Each arm of the MMC 120 may be configured to inject an electrical signal, indicated by the dashed lines in FIG. 2, into the respective strings 114 of the energy storage system 110. The response to the electrical signal may then be analysed as discussed above, either in terms of the response signal circulating back to the MMC 120 or other parameters, such as voltage, current or temperature, registered by sensors in the energy storage system 110.

Preferably, the MMC 120 is configured to inject an AC signal into the energy storage system 110, such that the energy exchanged between the energy storage system 110 and the power converter 120 is reduced. The current of the injected signal may for example be sinusoidal, square, sawtooth or triangular.

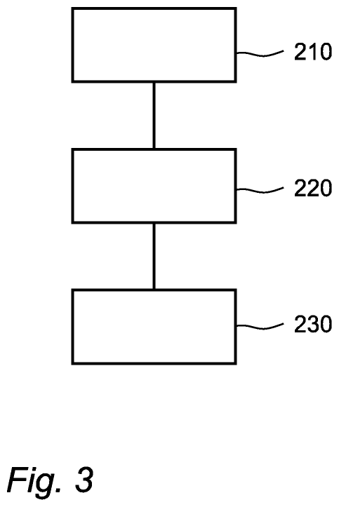

FIG. 3 is a flowchart illustrating a method for monitoring a status of an energy storage system 110 according to the embodiments disclosed in connection with FIGS. 1 and 2. The method may for example be embodied as computer-executable instructions distributed and used in form of a computer-program product including a computer-readable medium storing such instructions. As illustrated in the present figure, the method may comprise an act of generating 210, by the power converter 120, an electrical signal that is injected into the energy storage system 110, measuring 220 a response signal generated in response to the injected electrical signal, and determining 230 a status of the energy storage system 110 based on the received response signal. The acts may preferably be performed by the previously discussed control unit 130.

The person skilled in the art will realise that computer storage media include both volatile and non-volatile, removable and non-removable media implemented in any method or technology for storage of information such as computer readable instructions, data structures, program modules or other data. Further, it is known to the skilled person that communication media typically embody computer readable instructions, data structures, program modules or other data in a modulated data signal such as a carrier wave or other transport mechanisms and include any information delivery media. This listing of claims replaces all prior versions of and listings of claims.

1. A method for monitoring a status of an energy storage system connected to a power converter, wherein:
the energy storage system comprises a plurality of interconnected energy storage cells; and
the power converter is configured to convert power between alternating current (AC) and direct current (DC) and to output power from the energy storage system to an AC power transmission system and to charge the energy storage system with power from the AC power transmission system;
the method comprising:
generating, by the power converter, an electrical signal injected into the energy storage system;
measuring a response signal generated in response to the injected electrical signal; and
determining a status of the energy storage system based on the received response signal.

2. The method according to claim 1, wherein the electrical signal injected into the energy storage system is an alternating current.

3. The method according to claim 1, wherein the electrical signal injected into the energy storage system comprises a frequency being less than 50% of a sampling frequency of a control system of the power converter.

4. The method according to claim 1 wherein the electrical signal injected into the energy storage system comprises a frequency being an integer multiple of a fundamental frequency of the AC power transmission system.

5. The method according to claim 4, wherein the electrical signal injected into the energy storage system comprises a frequency corresponding to second or third harmonic frequency of the fundamental frequency of the AC power transmission system.

6. The method according to claim 1 wherein an amplitude of the electrical signal injected into the energy storage system is 10% or less of an amplitude of a charging current or load current of the energy storage system.

7. The method according to claim 1 wherein determining the status of the energy storage system comprises calculating an impedance based on a voltage and a current of the received response signal and comparing the calculated impedance with a reference value associated with the energy storage system.

8. The method according to claim 7, wherein a State of Health (SoH) of the energy storage system is determined based on a real part or an imaginary part of the impedance.

9. The method according to claim 7, wherein the reference value is obtained from previously performed measurements on the energy storage system or from a supplier of the energy storage system.

10. The method according to claim 1, wherein the response signal comprises information indicating a temperature of the energy storage system.

11. The method according to claim 10, wherein determining the status of the energy storage system comprises comparing the temperature of the energy storage system with an expected temperature.

12. The method according to claim 11, wherein the expected temperature is based on previous measurements of the temperature of the energy storage system or on predetermined temperature limits.

13. The method according to claim 1 wherein the status of the energy storage system comprises information of at least one of: an individual energy storage cell, a string formed by a plurality of energy storage cells, or the entire energy storage system.

14. A control unit configured to monitor a status of an energy storage system connected to a power converter, wherein the storage system comprises a plurality of interconnected energy storage cells and the power converter is configured to convert power between alternating current (AC) and direct current (DC) and to output power from the energy storage system to an AC power transmission system and to charge the energy storage system with power from the AC power transmission system, the control unit comprising:
an electrical signal generating function configured to cause the power converter to inject an electrical signal into the energy storage system; and
a status determining function configured to measure a response signal, generated in response to the injected electrical signal, and determine a status of the energy storage system based on the received response.

15. The control unit according to claim 14, wherein the status determining function is configured to receive the response signal from a battery management system (BMS).
